(19) United States
(12) Patent Application Publication
(10) Pub. No.: US 2019/0074149 A1
(43) Pub. Date: Mar. 7, 2019

(54) DC Voltage Switch

(71) Applicant: Siemens Aktiengesellschaft, Muenchen (DE)

(72) Inventor: Jürgen Rupp, Erlangen (DE)

(73) Assignee: Siemens Aktiengesellschaft, Muenchen (DE)

(21) Appl. No.: 16/084,484

(22) PCT Filed: Mar. 16, 2017
(86) PCT No.: PCT/EP2017/056224

§ 371 Date: Sep. 12, 2018

(30) Foreign Application Priority Data
Mar. 17, 2016 (DE) 10 2016 204 400.1

(51) Int. Cl. H01H 33/59; H03K 17/16

(52) U.S. Cl. CPC H01H 33/596; H03K 17/16

(57) ABSTRACT

Various embodiments may include a DC voltage switch comprising: a first and a second terminal for serial incorporation into a first pole of a DC voltage network; a shunt current path running between the terminals, including a semiconductor switch; an operating current path parallel to the shunt current path, comprising a mechanical switch in series with a primary-side winding of a transformer; a secondary-side winding of the transformer connected between a voltage source and a third terminal for incorporation into a second pole of the DC voltage network; a switch between the voltage source and the third terminal, in series with the secondary-side winding; a diode and a charging resistor connecting the voltage source to the first terminal; and a controller. The controller determines the voltage of the source after the mechanical switch has been opened and switches the switch at intervals to keep the voltage below a threshold.

### CROSS-REFERENCE TO RELATED APPLICATIONS

This application is a U.S. National Stage Application of International Application No. PCT/EP2017/056224 filed Mar. 16, 2017, which designates the United States of America, and claims priority to EP Application No. 10 2016 204 400.1 filed Mar. 17, 2016, the contents of which are hereby incorporated by reference in their entirety.

### TECHNICAL FIELD

The present disclosure relates to DC circuits. Various embodiments may include a DC voltage switch having two terminals, between which run an operating current path comprising a mechanical switch, and, in parallel therewith, a shunt current path comprising a semiconductor switch.

### BACKGROUND

The lack of a zero crossover means that switching off a DC current is more difficult than switching off an AC current. Whereas the arc that is produced on opening the contacts for the AC current, given a suitable design, is extinguished in the next zero crossover of the current, for the DC current it persists even over relatively large gaps until the switch is destroyed. Various approaches are used for a safe switch-off of a DC current. One such approach is based on generating a reverse current, which compensates for the load current, with the result that the current in a mechanical switch experiences a zero crossover. The switch can then be opened at zero current, so that an arc is not produced or extinguishes. In another approach, the current first commutates into a semiconductor switch, by means of which it can be switched off without an arc.

A general problem associated with switching off a DC current is that the energy stored inductively in the DC voltage network must be released in such a way as to avoid damaging the components of the DC voltage network. It is known to use voltage-limiting elements for this purpose. These have a limited service life however.

### SUMMARY

The teachings of the present disclosure may describe a DC voltage switch that allows improved removal of the energy stored inductively in the DC voltage network. For example, various embodiments may include a DC voltage switch comprising a first terminal and second terminal for incorporating serially into a first pole of a DC voltage network (10). Between the terminals runs a shunt current path comprising a semiconductor switch (15). Arranged in parallel with the shunt current path is an operating current path comprising a mechanical switch and, in series therewith, the primary-side winding of a transformer. The secondary-side winding of the transformer is connected between a voltage source and a third terminal for incorporating into a second pole (112) of the DC voltage network (10). Between the voltage source (161) and the third terminal is arranged a switch in series with the secondary-side winding of the transformer. The voltage source is connected via a diode and a charging resistor (162) to the first terminal (121). There is a controller (17) for controlling the switch (152), which controller is designed to determine repeatedly after the mechanical switch has been opened, the voltage of the voltage source (161), and to switch on the switch at intervals in such a way that the determined voltage remains below a definable threshold value.

In some embodiments, there is a second resistor connected in parallel with the secondary side of the transformer.

In some embodiments, there is a diode (271) connected in parallel with the secondary side of the transformer.

In some embodiments, the shunt current path comprises an additional semiconductor switch (25) connected in antiseries with the semiconductor switch (15) and the main current path comprises the primary side of an additional transformer (24).

In some embodiments, the secondary sides of the transformers (14, 24) are connected in series and the terminal of the secondary side of the additional transformer further away from the secondary side of the transformer is connected via an additional switch (252) to the third terminal (123).

In some embodiments, the voltage source comprises a capacitor (161).

In some embodiments, the capacitor is connected to a device for charging the capacitor.

In some embodiments, the mechanical switch is a switch having a switching time of less than 5 ms.

In some embodiments, there is a switch for short-circuiting the secondary-side winding of the transformer.

In some embodiments, the voltage source is a DC-link capacitor of a converter.

As another example, some embodiments include a HVDC transmission network comprising a DC voltage switch as described above.

As another example, some embodiments include a vehicle, in particular rail vehicle, comprising a DC voltage switch as described above.

### BRIEF DESCRIPTION OF THE DRAWINGS

Exemplary embodiments of the teachings herein are explained in greater detail with reference to the figures of the drawing, in which the features are shown schematically and:

FIG. 1: shows a unidirectional DC voltage switch in part of a DC voltage network according to teachings of the present disclosure; and

FIG. 2: shows a bidirectional DC voltage switch in part of a DC voltage network according to teachings of the present disclosure.

### DETAILED DESCRIPTION

In some embodiments, a DC voltage switch comprises a first terminal and second terminal for serial incorporation in a first pole of a DC voltage network. Between the terminals runs a shunt current path comprising a semiconductor switch and, in parallel with the shunt current path, an operating current path comprising a mechanical switch and, in series therewith, the primary-side winding of a transformer. The secondary-side winding of the transformer is connected between a voltage source and a third terminal for incorporating into a second pole of the DC voltage network. Between the voltage source and the third terminal is arranged a switch in series with the secondary-side winding of the transformer. The voltage source is also connected via a diode and a charging resistor to the first terminal. Finally, there is a controller for controlling the switch, which controller is designed to determine repeatedly after the mechanical switch has been opened, the voltage of the voltage source, and to switch on the switch at intervals in such a way that the determined voltage remains below a definable threshold value. In some embodiments, the energy stored inductively in the DC voltage network may be released directly via the switch. Other elements for overvoltage limiting such as varistors are not needed. If the controller has switched off the switch, the voltage across the voltage source increases with time as long as there is still energy stored inductively. The controller detects the voltage across the voltage source continuously or at intervals. If the voltage exceeds or reaches a definable threshold value, which lies above the operating voltage of the DC voltage network, the switch is switched on. This creates a current path from the first pole of the DC voltage network to the second pole of the DC voltage network. This produces a time-limited freewheeling circuit, and the voltage across the voltage source drops.

In some embodiments, the controller switches the switch off again if the voltage falls below a further threshold value. The further threshold value can be less than or equal to the threshold value. The further threshold value may also lie above the operating voltage of the DC voltage network.

In some embodiments, the following features can be included with the DC voltage switch:
The third terminal can be connected also to another ground potential instead of to a second pole of the DC voltage network.
A second resistor can be connected in parallel with the secondary side of the transformer. This resistor may be dimensioned such that at least the maximum current to be switched off at the rated voltage can flow away.
A diode can be connected in parallel with the secondary side of the transformer.
The shunt current path can comprise two antiseries-connected semiconductor switches, and the main current path can comprise the primary side of an additional transformer. The DC voltage switch can thereby be designed as a bidirectional switch. In other words, this allows the switch to switch off DC current in both directions. If the secondary sides of the transformers are connected in series, the terminal of the secondary side of the additional transformer further away from the secondary side of the transformer may be connected via an additional switch to the third terminal.
In some embodiments, the voltage source comprises an energy storage device, e.g. a capacitor. A capacitor is suitable for rapid dissipation of the necessary energy in order to compensate for a short-circuit current or even a normal operating current in the DC voltage network, and thereby force a zero crossover of the current.
The voltage source can be provided as a separate device, for instance as a separate capacitor connected to the transformer independently of other components of the DC voltage network. It is thereby possible to ensure, for instance by a dedicated charging circuit for the voltage source, readiness of the voltage source regardless of other circumstances.
The voltage source can be arranged as part of an additional circuit, for instance as a DC-link capacitor of a converter, which, for example, is otherwise related to the DC voltage network. This reuses existing resources of the design and hence achieves a saving on components overall.
The mechanical switch can have a switching time of less than 5 ms. Since the zero crossover of the current is based on the discharging of an energy store, the time period within which a zero crossover of the current takes place is typically limited to just a few milliseconds. The mechanical switch can open within this time in order to achieve safe suppression or extinguishing of the arc.
In some embodiments, the secondary-side winding of the transformer can be short-circuited. For this purpose, for example, a connection furnished by a semiconductor switch or a fast mechanical switch can be provided between the winding ends of the secondary-side winding of the transformer. Short-circuiting the secondary-side winding of the transformer reduces the inductance of the primary-side winding of the transformer to a very low value, and hence reduces the effect of the primary-side winding of the transformer on the properties of the DC voltage network.

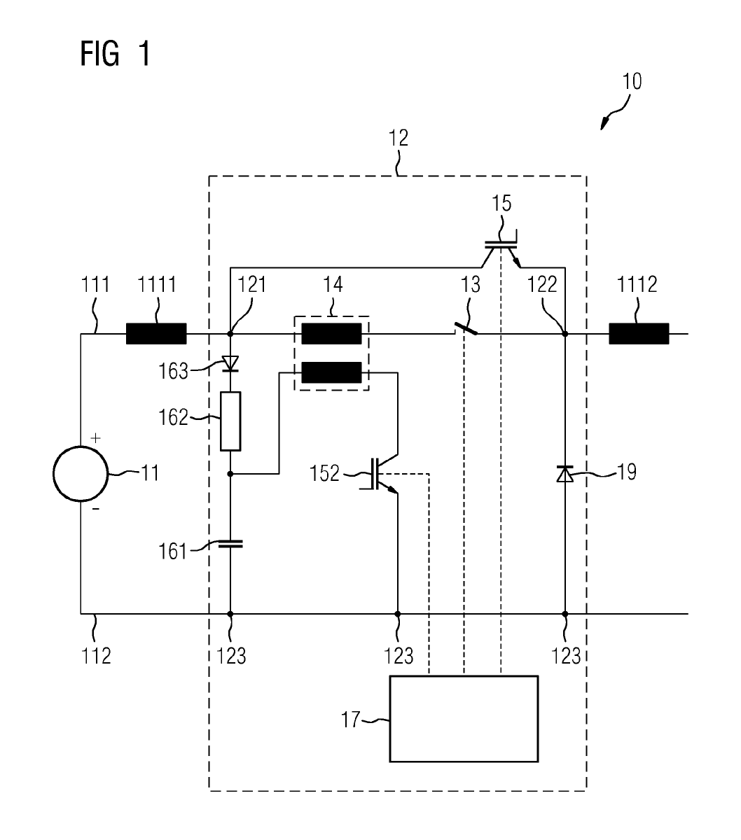

FIG. 1 shows an exemplary embodiment including a DC voltage switch 12 in part of a DC voltage network 10. The DC voltage network 10 is fed from a DC voltage source 11 and thereby supplied with a DC voltage. The DC voltage network 10 may be a network in HVDC electric power transmission or, for example, a network in a vehicle, for instance in a locomotive or a railcar or in the region of the feed into a network for electrically driven vehicles. The principle can basically be applied to all voltage levels from low voltage through medium voltage up to high voltage. The DC voltage switch 12 is arranged between the load (not shown) and the DC voltage source 11. The DC voltage switch 12 is incorporated serially into a first pole 111 of the DC voltage network 10 by a first connecting terminal and second connecting terminal 121, 122. A third connecting terminal 123 is connected to a second pole of the DC voltage network 10.

Between first and second connecting terminals 121, 122, the DC voltage switch 12 comprises a series circuit composed of the primary-side winding of a transformer 14 and a mechanical switch 13. This series circuit constitutes the main current path, through which the current flows during normal operation of the DC voltage network 10. The mechanical switch 13 and the primary winding of the transformer 14 have an extremely low resistance and therefore generate only very low losses. Arranged in parallel with the series circuit is a main switch 15 in the form of an IGBT, which constitutes a shunt current path, through which flows no current or only very little current during normal operation because the IGBT, even when in the on state, has a significantly higher resistance or voltage drop than the mechanical switch 13.

The DC voltage switch 12 also comprises a freewheeling path via a freewheeling diode 19 as a connection between the second and third connecting terminals 122, 123. The freewheeling path is optional and is included if the energy stored in the network inductance 1111, for instance in cables, may potentially result in damage when there is a rapid interruption in current. Originating from the first of the connecting terminals 121, to which the primary winding of the transformer 14 is closer, is a further connection via a diode 163 and a charging resistor 162 to a capacitor 161. The terminal of the capacitor 161 located on the other side thereof is connected to the third connecting terminal 123.

The potential point between the capacitor 161 and the charging resistor 162 is connected to the secondary winding of the transformer 14. Continuing therefrom is arranged a switch 152 in the form of an IGBT, the second terminal of which is connected to the third connecting terminal 123 and hence to the second pole of the DC voltage network 10. In the normal operating situation, the switch 152 is off and therefore the capacitor 161 cannot be discharged. The capacitor 161 may be in the charged state in the normal operating situation.

The necessary voltage for the capacitor 161 and hence the exact design of the components can be defined by the choice of the transformation ratio in the transformer 14. For instance, the components can be optimized for rapid switch-off or for small overall dimensions. Values between 0.01 and 0.1 are advantageously used for the winding turns ratio between the primary side and the secondary side of the transformer 14. On the secondary side is needed only a voltage that is greater than the voltage drop across the semiconductors for the current to be commutated, which for a low-voltage application lies below 10V. The necessary capacitance of the capacitor 161 and the height of the necessary charging voltage are obtained from the voltage of the DC voltage network 10 and the transformation ratio of the transformer 14.

During normal operation, the entire current flows through the mechanical switch 13. In order to initiate the switch-off process, a controller 17 for the DC voltage switch 12 first switches on the main switch 15. Owing to the larger on-state resistance, only a small portion of the current will initially commutate from the mechanical switch 13 into the main switch 15. To force this commutation, the switch 152 is switched on, thereby discharging the capacitor 161 via the transformer 14. This generates a voltage in the main current path comprising the mechanical switch 13, with the result that the current commutates fully into the main switch 15. Then the mechanical switch 13 is opened at zero current, and the switch 152 is closed again. In the final step, the main switch 15 must now also be switched off in order to interrupt the current flow completely.

The stored energy in the network inductance 1112 can be discharged via the freewheeling diode 19. The energy in the network inductance 1111 would generate a high overvoltage at the input of the DC voltage switch 12. To release this energy and to limit the voltage, the switch 152 is now again switched on and off periodically. The energy in the charging resistor 162 is thereby converted into heat, and the current flow released through network inductance 1111, diode 163 and charging resistor 162. In the pulse pauses, when the switch 152 is off, the current can continue to flow into the capacitor 161 so that there is not a rapid cut-off in the current. During the times in which the switch 152 is on, the capacitor 161 is then discharged again slightly in order to limit the voltage.

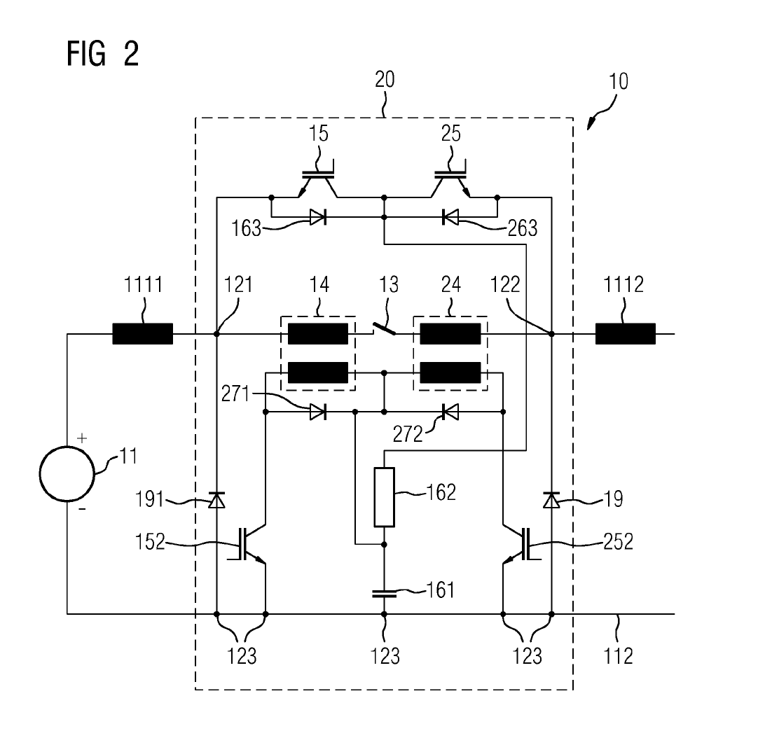

FIG. 2 shows a second exemplary embodiment of the teachings here. The DC voltage switch 20 according to FIG. 2, unlike the DC voltage switch 12 of FIG. 1, is designed to be able to work bidirectionally, i.e. to be able to switch off of a current flow in both directions. Corresponding components of the two DC voltage switches 12, 20 are denoted by the same reference signs. In this embodiment, the DC voltage switch 20 is again incorporated serially into the first pole 111 of the DC voltage network 10 by a first connecting terminal and second connecting terminal 121, 122. A third connecting terminal 123 is connected to the second pole of the DC voltage network 10.

Between first and second connecting terminals 121, 122, the DC voltage switch 20 comprises a series circuit composed of the primary-side winding of the transformer 14, the mechanical switch 13, and the primary-side winding of an additional transformer 24. This series circuit constitutes the main current path, through which the current flows during normal operation of the DC voltage network 10. Arranged in parallel with the series circuit is an additional series circuit composed of the main switch 15 and the additional main switch 25 arranged in antiseries, which series circuit constitutes the shunt current path. Connected in parallel with the main switch 15 is diode 163, which can be integrated as a component in the main switch 15. Connected in parallel with the additional main switch 25 is diode 263, which can be integrated as a component in the additional main switch 25.

The DC voltage switch 12 also comprises a freewheeling path via a freewheeling diode 19 as a connection between the second and third connecting terminals 122, 123, and an additional freewheeling path comprising an additional freewheeling diode 191 between the first and third connecting terminals 121, 123. Originating from the potential point between the main switch 15 and the additional main switch 25 is a connection via the charging resistor 162 to the capacitor 161. The terminal of the capacitor 161 located on the other side thereof is connected to the third connecting terminal 123.

The potential point between the capacitor 161 and the charging resistor 162 is connected to the secondary winding of the transformer 14. Continuing therefrom is arranged the switch 152, the second terminal of which is connected to the third connecting terminal 123 and hence to the second pole of the DC voltage network 10. Between the switch 152 and the capacitor 161 is arranged a diode 271 in parallel with the secondary winding of the transformer 14.

The potential point between the capacitor 161 and the charging resistor 162 is additionally connected to the secondary winding of the additional transformer 24. Continuing therefrom is arranged an additional switch 252, the second terminal of which is connected to the third connecting terminal 123 and hence to the second pole of the DC voltage network 10. Between the additional switch 252 and the capacitor 161 is arranged a diode 272 in parallel with the secondary winding of the additional transformer 24. In other words, the bidirectional DC voltage switch 20 comprises two antiseries-connected unidirectional DC voltage switches 12, in which the elements mechanical switch 13, charging resistor 162 and capacitor 161 are needed only once.

When a current from left to right, i.e. from the side of the network inductance 1111, is switched off, the pulse generation by the switch 152 and the transformer 14 is used to generate the commutation voltage and to release the energy in the network inductance 1111. Freewheeling diode 19 is used to release the energy in network inductance 1112.

When a current from right to left is switched off, the pulse generation by the additional switch 252 and the additional transformer 24 is used to generate the commutation voltage and to release the energy in the network inductance 1112. The freewheeling diode 191 is used to release the energy in network inductance 1111. The two diodes 271, 272 in parallel with the secondary windings of the transformers 14, 24 act as a freewheeling circuit for the parasitic inductances and can also be substituted by resistors, similar to the unidirectional DC voltage switch 12.

What is claimed is:

1. A DC voltage switch comprising:
a first terminal and a second terminal for serial incorporation into a first pole of a DC voltage network;
a shunt current path running between the terminals, the shunt current path comprising a semiconductor switch;
an operating current path arranged in parallel to the shunt current path, the operating current path comprising a mechanical switch and, in series therewith, a primary-side winding of a transformer;
wherein a the secondary-side winding of the transformer is connected between a voltage source and a third terminal for incorporation into a second pole of the DC voltage network;
a switch between the voltage source and the third terminal, the switch in series with the secondary-side winding of the transformer;
a diode and a charging resistor connecting the voltage source to the first terminal; and
a controller for actuating the switch, the controller determining the voltage of the voltage source after the mechanical switch has been opened;
wherein the controller switches on the switch at intervals to keep the determined voltage below a defined threshold value.

2. The DC voltage switch as claimed in claim 1, further comprising—a second resistor connected in parallel with the secondary side of the transformer.

3. The DC voltage switch as claimed in claim 1, further comprising a diode connected in parallel to the secondary side of the transformer.

4. The DC voltage switch as claimed in claim 1, wherein:the shunt current path comprises a second semiconductor switch connected in antiseries with the semiconductor switch; and the main current path comprises a primary side of an additional transformer.

5. The DC voltage switch as claimed in claim 4, wherein:
the secondary sides of the transformer and the additional transformer are connected in series;
the terminal of the secondary side of the additional transformer further away from the secondary side of the transformer is connected via an additional switch to the third terminal.

6. The DC voltage switch as claimed in claim 1, wherein the voltage source comprises a capacitor.

7. The DC voltage switch as claimed in claim 6, further comprising a charger connected to the capacitor.

8. The DC voltage switch as claimed in claim 1, wherein the mechanical switch comprises a switch having a switching time of less than 5 ms.

9. The DC voltage switch as claimed in claim 1, further comprising a switch for short-circuiting the secondary-side winding of the transformer.

10. The DC voltage switch as claimed in claim 1, wherein the voltage source comprises a DC-link capacitor of a converter.

11-12. (canceled)
